(19) United States
(12) Patent Application Publication
(10) Pub. No.: US 2026/0253608 A1
(43) Pub. Date: Aug. 27, 2026

(54) DIE SET FOR TEARING SHEET MATERIAL AND METHOD FOR TEARING SHEET MATERIAL

(71) Applicant: NHK SPRING CO., LTD., Yokohama-shi (JP)

(72) Inventor: Koichi IMOTO, Yokohama-shi (JP)

(73) Assignee: NHK SPRING CO., LTD., Yokohama-shi (JP)

(21) Appl. No.: 19/537,563

(22) Filed: Feb. 12, 2026

(30) Foreign Application Priority Data
Feb. 21, 2025 (JP) 2025-026347

(51) Int. Cl. G11B 5/48; B29C 48/08; B29C 51/44; H10W 90/00

(52) U.S. Cl. CPC G11B 5/4833; B29C 48/08; B29C 51/44; H10W 90/00; H10W 90/734

(57) ABSTRACT

A die set includes a first die unit which fixes a first portion of a sheet material and a second die unit which fixes a second portion of the sheet material. A fulcrum portion is formed at a position facing the sheet material. The fulcrum portion has a first support surface and a second support surface extending in an oblique direction toward a weakened portion. The first support surface generates a tensile force to tear off a part near one end of the weakened portion while the amount of movement of the second die unit relative to the first die unit is small. The second support surface generates a tensile force to tear off a part near the other end of the weakened portion as the amount of relative movement of the second die unit increases.

### CROSS-REFERENCE TO RELATED APPLICATIONS

This application is based upon and claims the benefit of priority from prior Japanese Patent Application No. 2025-026347, filed February 21, 2025, the entire contents of which are incorporated herein by reference.

### BACKGROUND OF THE INVENTION

### 1. Field of the Invention

The present invention relates to a die set for tearing a sheet material, such as that used in disk device suspensions, and a method for tearing such a sheet material.

### 2. Description of the Related Art

Hard disk devices are used in information processing devices such as personal computers. Hereinafter, the hard disk device may be referred to as a disk device. The disk device includes a magnetic disk rotating around a spindle, a carriage pivoting around a pivot axis and the like. A suspension for the disk device is provided on the arm of the carriage. Hereinafter, the suspension for the disk device may be referred to simply as a suspension.

The suspension has a base plate made of a metal such as stainless steel, a load beam, a flexure disposed along the load beam, and the like. Depending on the specifications of the suspension, a plate-shaped spring member may be provided between the base plate and the load beam. The spring member is made from a metal plate thinner than the base plate. In one example of the suspension, one end of the spring member is fixed to the base plate by a fixing means such as welding. Further, the other end of the spring member is fixed to the load beam.

Generally, in the manufacturing process of the suspension, the spring member, which is used in the product, and a frame portion, which becomes scrap, are formed to be integrated with a metal-plate blank. For example, the spring member is fixed to the base plate by laser spot welding or the like. After that, the joint portion between the frame portion and the spring member is severed. When the joint portion is located on an outer side of the outline of the base plate, the joint portion can be cut with a cutting tool such as a cutter.

On the other hand, when the joint portion is located on an inner side of the outline of the base plate, cutting tools cannot be used. Therefore, as discussed in JP 2012-27993 A (Patent Literature 1) or JP 2021-93231 A (Patent Literature 2), it is proposed to tear off a weakened portion formed in the sheet material using a die. For example, by forming a plurality of holes in series between the frame portion and the spring member, a weakened portion is formed. To this weakened portion, tension is applied using a die set. With this tension, the weakened portion can be torn off.

In the tearing method described in Patent Literature 1, tension is generated in a direction parallel to the surface of the sheet material by devising the operation of the punch and the guide portion of the die apparatus. However, in this case, tension acts on the entire weakened portion substantially at the same timing, there is a concern that relatively large vibrations and noise occur at the instant when the weakened portion is torn off.

The tearing method described in Patent Literature 2 focuses on devising the shape of a plurality of holes constituting the weakened portion. With this configuration, the weakened portion to be torn off relatively easily. However, in this case, the shape of the holes formed in the above-mentioned weakened portion is not ordinary, the technique entails disadvantageous formation of holes. Further, there is room for improvement regarding the shape of the tear mark left after the weakened portion is torn off.

An object of one embodiment is to provide a die set which can tear off a weakened portion of a sheet material and a method for tearing off the sheet material.

### BRIEF SUMMARY OF THE INVENTION

According to one embodiment, a die set comprises a first die unit which fixes a first portion of the sheet material, a second die unit which fixes a second portion of the sheet material, and a fulcrum portion located facing the sheet material. The second die unit moves relative to the first die unit in the thickness direction of the sheet material. The fulcrum portion is brought into contact with the sheet material in a state where the first die unit and second die unit move relative to each other in the thickness direction and generates a tensile force to tear the sheet material.

The fulcrum portion includes a first support surface and a second support surface. The first support surface is located at a position to generate a tensile force to tear a part of the sheet material near one end of a weakened portion when the amount of movement of the second die unit relative to the first die unit is small. The second support surface is located at a position to generate a tensile force to tear a part of the sheet material near the other end of the weakened portion when the amount of movement of the second die unit relative to the first die unit increases.

The first support surface and the second support surface have such an oblique shape that, when viewed from a direction parallel to the plane of the sheet material, the distance from the sheet material increases from the side closer to the one end of the weakened portion toward the side closer to the other end. Alternatively, the first support surface and the second support surface may have an inclined shape such that, as viewed from a direction facing the plane of the sheet material, the distance from the weakened portion decreases from the side closer to one end of the weakened portion toward the side closer to the other end.

According to the one embodiment, in a method for tearing off a sheet material, a first portion of the sheet material is fixed by the first die unit. A second portion of the sheet material is fixed by a second die unit. Then, by moving the first die unit and the second die unit relative to each other in the thickness direction of the sheet material, the sheet material is brought into contact with the fulcrum portion and a tensile force is generated by the fulcrum portion to tear off the weakened portion. Moreover, in the tearing method of this embodiment, while the amount of movement of the second die unit relative to the first die unit is small, a tensile force to tear a part near one end of a weakened portion of the sheet material is generated by the first support surface of the fulcrum portion. As the amount of movement of the second die unit relative to the first die unit increases, a tensile force to tear off a part near the other end of the weakened portion of the sheet material is generated by the second support surface of the fulcrum portion.

According to the die set and tearing method of one embodiment, a weakened portion formed in a sheet material can be sequentially torn from the side near one end of the weakened portion to the side near its other end. According to one embodiment, it may be advantageous, for example, in suppressing the generation of vibration and noise during tearing.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a schematic plan view showing an example of a suspension for a disk device.

FIG. 2 is a plan view showing a part of the suspension for the disk device shown in FIG. 1 and a part of a sheet material.

FIG. 3 is a schematic perspective view showing a first die unit and a second die unit of a die set according to the first embodiment.

FIG. 4 is a perspective view showing the state where the first die unit and the second die unit shown in FIG. 3 move relative to each other.

FIG. 5 is a cross-sectional view of the die set taken along the line F5-F5 in FIG. 3.

FIG. 6 is a cross-sectional view of the die set taken along the line F6-F6 in FIG. 3.

FIG. 7 is a cross-sectional view of the die set taken along the line F7-F7 in FIG. 3.

FIG. 8 is a perspective view of a part of the first die unit shown in FIG. 3.

FIG. 9 is a cross-sectional view of a part of the first die unit taken along the line F9-F9 in FIG. 8.

FIG. 10 is a cross-sectional view of parts of the die set and sheet material taken along the line F10-F10 in FIG. 3.

FIG. 11 is a cross-sectional view of parts of the die set and sheet material taken along the line F11-F11 in FIG. 4.

FIG. 12 is a cross-sectional view showing the sheet material torn by the die set shown in FIG. 3.

FIG. 13 is a plan view showing a part of the sheet material and a part of the base component shown in FIG. 2.

FIG. 14 is a plan view showing the state where the sheet material and base component shown in FIG. 13 are placed on the first die and third die.

FIG. 15 is a plan view showing the state where the second die and fourth die overlap a part of the sheet material and the base component shown in FIG. 13.

FIG. 16 is a plan view showing a part of the sheet material in which the weakened portion is torn off and a part of the base component.

FIG. 17 is a plan view showing a part of the die set and a part of the sheet material according to the second embodiment.

FIG. 18 is a cross-sectional view showing a part of the die set shown in FIG. 17 and a sheet material in the process of being torn off.

### DETAILED DESCRIPTION OF THE INVENTION

### First Embodiment

A die set and a method for tearing a sheet material according to the first embodiment will now be described with reference to FIGS. 1 to 16.

FIG. 1 is a plan view schematically showing an example of a suspension 1 for a disk drive. The suspension 1 for a disk drive includes a base component 2 such as a base plate, a load beam 3, and a pair of plate components 4 and 5 that function as a hinge portion. The base component 2 is formed, for example, from a metal plate such as of stainless steel. The plate components 4 and 5 are each formed, for example, from a metal plate such as of stainless steel, having a thickness less than that of the base component 2.

The plate components 4 and 5 are provided between the base component 2 and the load beam 3. The plate components 4 and 5 are each fixed to the base component 2 by weld portions 6a. The plate components 4 and 5 are each fixed to the load beam 3 by weld portions 6b. The weld portions 6a and 6b are formed, for example, by laser spot welding.

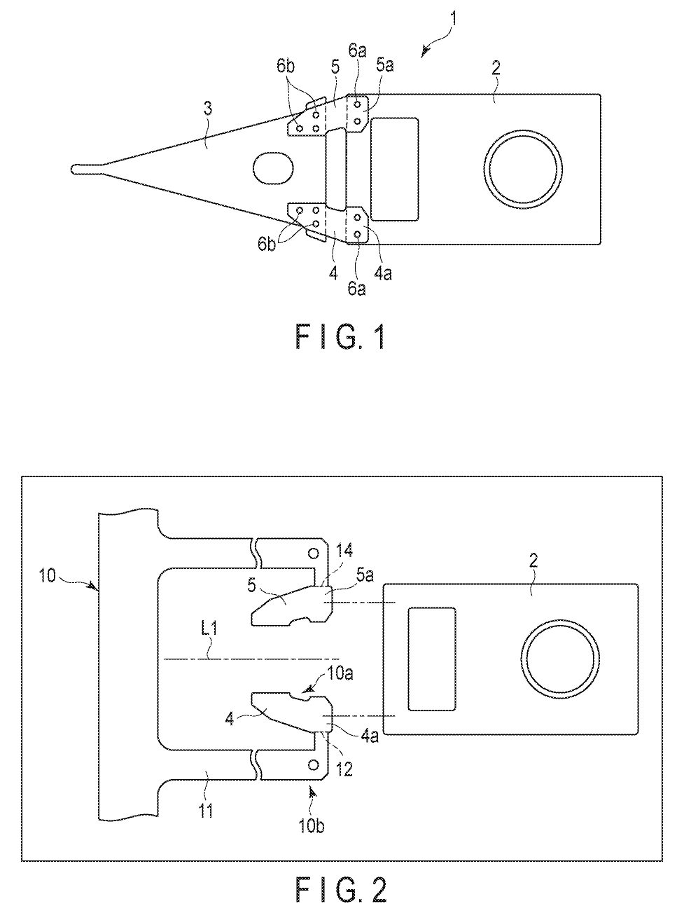

FIG. 2 shows a part of a sheet material 10 used in the manufacturing process of the suspension 1 and the base component 2. The sheet material 10 is made from a metal plate such as of stainless steel, and may be in some cases referred to as a blank. The sheet material 10 includes the plate components 4 and 5 to be used in the product and a frame portion 11 that becomes scrap. The plate components 4 and 5 are an example of a first portion 10a of the sheet material 10. The frame portion 11 is an example of a second portion 10b of the sheet material 10.

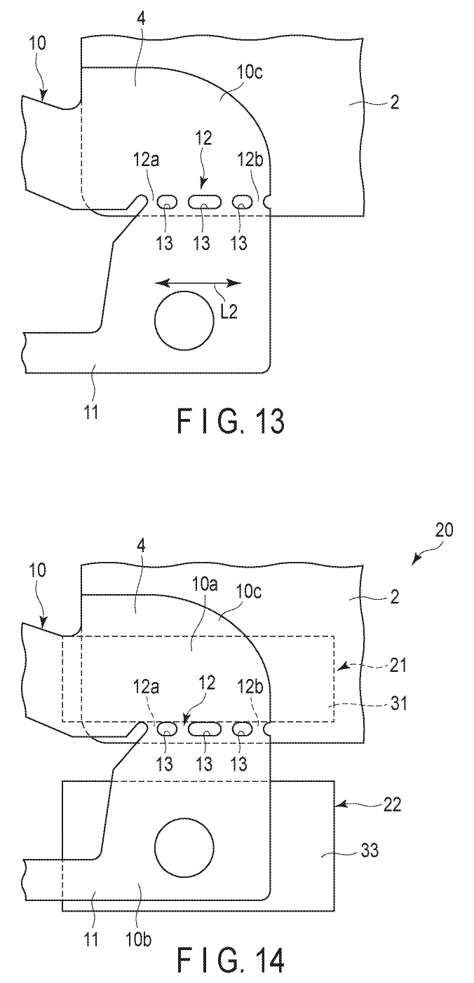

The weakened portion 12 to be separated is formed at the joint portion between the first plate component 4 and the frame portion 11. A plurality of holes 13 (shown in FIG. 13 and the like) are formed in series within the weakened portion 12 to reduce its mechanical strength against tearing force. A similar weakened portion 14 is formed between the second plate component 5 and the frame portion 11 as well.

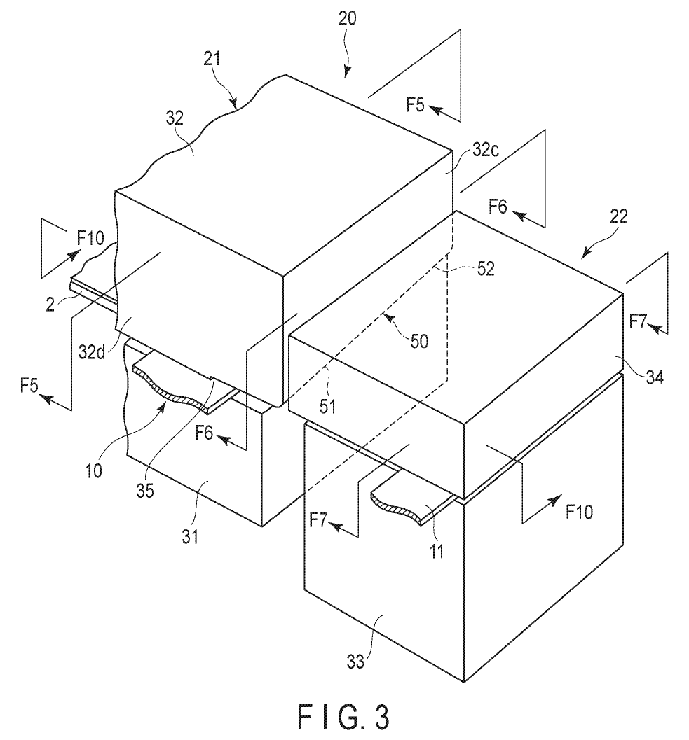

During the manufacturing process of the suspension 1, the end portion 4a of the first plate component 4 provided on the sheet material 10 and the end portion 5a of the second plate component 5 are each overlaid on the base component 2. Then, the end portion 4a of the first plate component 4 and the end portion 5a of the second plate component 5 are each fixed to the base component 2 by laser spot welding or the like. Subsequently, the weakened portions 12 and 14 are torn off by the die set 20 (shown in FIGS. 3 to 12).

As shown in FIG. 2, the first plate component 4 and the second plate component 5 have a line-symmetric shape with a straight line L1 as the axis of symmetry. The first plate component 4 and the second plate component 5 have substantially common configurations, and therefore the following description focuses on the case where the weakened portion 12 of the first plate component 4 is torn off.

FIG. 3 is a perspective view schematically showing a part of the die set 20. The die set 20 includes a first die unit 21 located on a left side in FIG. 3 and a second die unit 22 located on a right side. The first die unit 21 includes a first die 31 and a second die 32. The second die unit 22 includes a third die 33 and a fourth die 34.

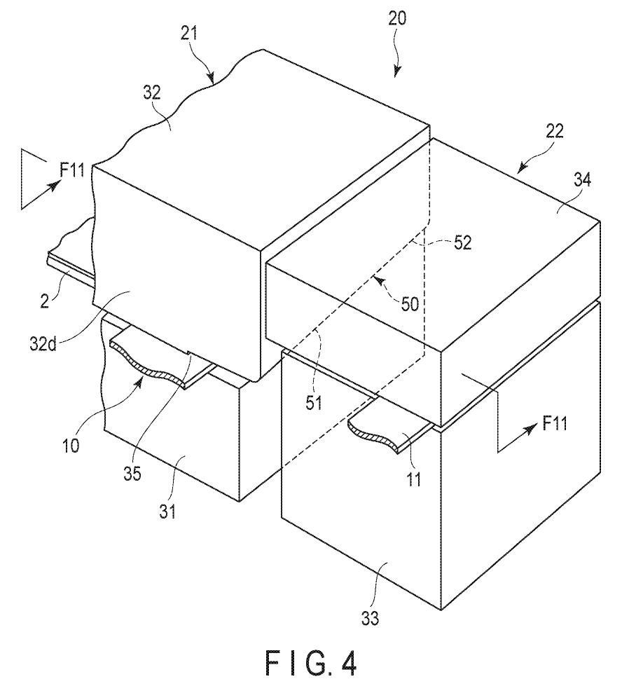

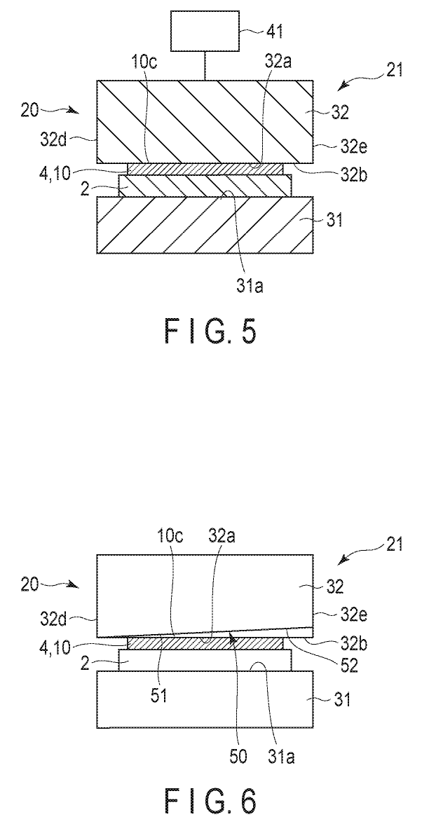

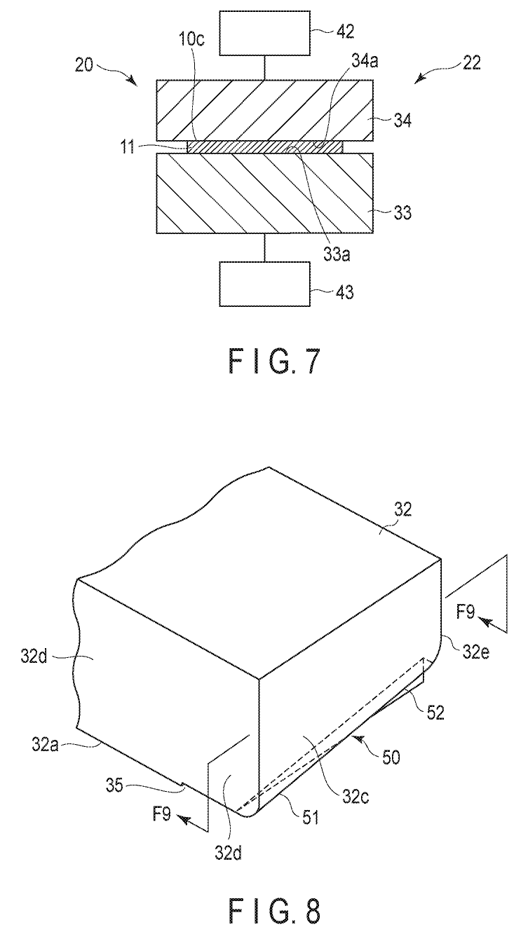

FIG. 4 shows the state where the second die unit 22 moved (ascended) relative to the first die unit 21. FIG. 5 is a schematic cross-sectional view of the die set 20 taken along the line F5-F5 in FIG. 3. FIG. 6 is a schematic cross-sectional view of the die set 20 taken along the line F6-F6 in FIG. 3. FIG. 7 is a schematic cross-sectional view of the die set 20 taken along the line F7-F7 in FIG. 3.

As shown in FIGS. 5 and 6, the first die 31 has a surface 31a that supports the base component 2. The second die 32 has a surface 32a that presses the plate component 4. An example of the first die 31 is a lower pad, and an example of the second die 32 is a punch. The base component 2 and the plate component 4 are disposed to be stacked between the first die 31 and the second die 32. A step portion 35 (shown in FIG. 10 and the like) is formed on the lower surface 32b of the second die 32 at a position corresponding to the weakened portion 12. With the step portion 35 thus formed, a gap G can be surely maintained between the first die 31 and the second die 32 during die closure, thereby preventing the weakened portion 12 from being constrained.

The first die 31 and the second die 32 can move relative to each other in the directions of opening and closing by the first drive mechanism 41 (shown in FIG. 5). By closing the first die 31 and the second die 32, the base component 2 and the plate component 4 are clamped along the thickness direction. That is, the base component 2 and the first portion 10a of the sheet material 10 are fixed by the first die unit 21.

An example of the third die 33 is a die, and an example of the fourth die 34 is an upper pad. The third die 33 and the fourth die 34 can move relative to each other in the opening and closing directions by the second drive mechanism 42 (shown in FIG. 7). As can be seen in FIG. 7, the third die 33 has a surface 33a that supports the frame portion 11. The fourth die 34 has a surface 34a that presses against the frame portion 11. By closing the third die 33 and the fourth die 34, the frame portion 11 are clamped along the thickness direction. That is, the second portion 10b of the sheet material 10 is fixed by the second die unit 22.

The first die unit 21 and the second die unit 22 can move relative to each other between a first position (shown in FIG. 3) and a second position (shown in FIG. 4). For example, relative to the first die unit 21, the second die unit 22 can move in up and down directions by means of the drive mechanism 43 (shown in FIG. 7).

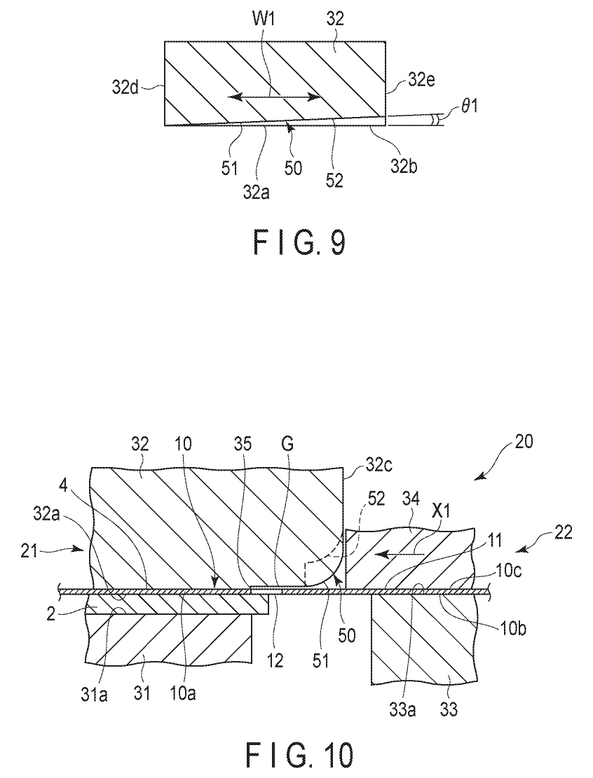

FIG. 8 is a perspective view showing the end portion of the second die 32. FIG. 9 is a cross-sectional view of the second die 32 taken along the line F9-F9 in FIG. 8. A fulcrum portion 50 is formed at the corner portion where the lower surface 32b and side surface 32c of the second die 32 intersect each other. As shown in FIG. 10, the vertical cross-section of the fulcrum portion 50 forms a curved surface shape that curves like an arc form from the lower surface 32b of the second die 32 toward the side surface 32c. The fulcrum portion 50 extends in the width direction of the second die 32 (the direction indicated by arrow W1 in FIG. 9). In other words, the fulcrum portion 50 extends in the lengthwise direction of the weakened portion 12.

The fulcrum portion 50 is located at a position facing the plane 10c of the sheet material 10. The fulcrum portion 50 is brought into contact with the sheet material 10 when the second die unit 22 moves relative to the first die unit 21 in the thickness direction of the sheet material 10. Then, in a state where the second die unit 22 is relatively raised, a tensional force is generated on the sheet material 10 to tear off the weakened portion 12.

As shown in FIG. 9, the fulcrum portion 50 extends in an oblique direction from one end 32d to the other end 32e of the second die 32, such as to form an angle θ1 with respect to the lower surface 32b of the second die 32. That is, as viewed from a direction parallel to the plane 10c of the sheet material 10 (indicated by arrow X1 in FIG. 10), the fulcrum portion 50 has an oblique shape where the distance from the sheet material 10 increases from the side closer to one end 12a of the weakened portion 12 toward the side closer to the other end 12b. The height difference between one end and the other end of the fulcrum portion 50 is approximately around the thickness of the sheet material 10.

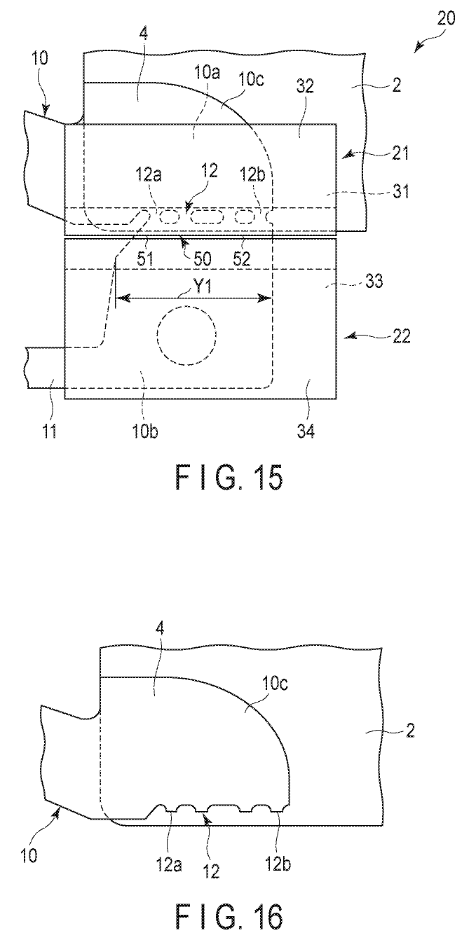

The angle θ1 of the fulcrum portion 50 is 1° or more, 5° or less, and preferably 1° or more, 3° or less. When θ1 is less than 1°, the desired effect cannot be achieved. When θ1 exceeds 5°, excessive stress may be generated in the sheet material 10. Note here that θ1 is a small value, but in FIGS. 8 and 9, the angle is exaggerated for illustrative purposes. The fulcrum portion 50 extends along the lengthwise direction of the weakened portion 12, over a board width Y1 (shown in FIG. 15) that exceeds the length of the weakened portion 12.

The fulcrum portion 50 of this embodiment includes a first support surface 51 and a second support surface 52 with respect to the length direction of the weakened portion 12 (the directions indicated by the bidirectional arrow L2 in FIG. 13). The first support surface 51 is located on a side closer to the one end 12a of the weakened portion 12. The second support surface 52 is located on a side closer to the other end 12b of the weakened portion 12. As shown in FIGS. 8 and 9, the first support surface 51 and the second support surface 52 are continuous with each other, extending from the one end 32d to the other end 32e of the second die 32, such as to form the angle θ1.

The second die unit 22 moves relative to the first die unit 21. The first support surface 51 is formed at a position that generates a tensile force for tearing on the portion close to the one end 12a of the weakened portion 12 while the movement amount of the second die unit 22 is small. In contrast, the second support surface 52 is formed at a position that generates a tensile force for tearing the portion near the other end 12b of the weakened portion 12 when the movement amount of the second die unit 22 becomes large.

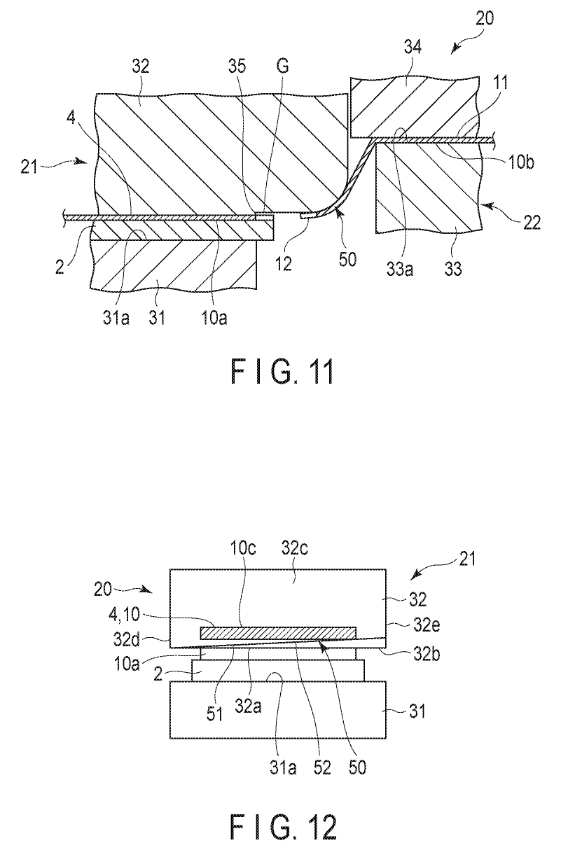

FIG. 11 shows the state where the weakened portion 12 has been torn off as the second die unit 22 rises relative to the first die unit 21. When the second die unit 22 moves upward relative to the first die unit 21, the frame portion 11 fixed to the second die unit 22 moves upward relative to the plate component 4. At this time, a tearing tensile force acts on the weakened portion 12, and thus the weakened portion 12, which has lower strength, is torn off. Note that the first die unit 21 may as well be moved downward relative to the second die unit 22. FIG. 12 is a cross-sectional view showing the torn sheet material 10.

FIG. 13 shows a part of the base component 2 and a part of the sheet material 10 before the weakened portion 12 is torn off. FIG. 14 shows the state where the base component 2 and the sheet material 10 are placed on the first die 31 and the third die 33. FIG. 15 shows the state where the second die 32 and the fourth die 34 are placed on the base component 2 and the sheet material 10.

During the process of tearing off the weakened portion 12, as shown in FIG. 14, the base component 2 and the plate component 4 are placed on the first die 31. Then, the frame portion 11 of the sheet material 10 is placed on the third die 33. Further, as shown in FIG. 15, the second die 32 and the fourth die 34 are placed on the sheet material 10. Then, the base component 2 and the plate component 4 are clamped in the thickness direction by the first die 31 and the second die 32. Further, the frame portion 11 is clamped in the thickness direction by the third die 33 and the fourth die 34.

As described above, the base component 2 and the plate component 4 are fixed by the first die unit 21, and the frame portion 11 is fixed by the second die unit 22. The plate component 4 is an example of the first portion 10a of the sheet material 10. The frame portion 11 is an example of the second portion 10b of the sheet material 10.

The first portion 10a is fixed by the first die unit 21, and the second portion 10b is fixed by the second die unit 22. In this state, the second die unit 22 moves relative to the first die unit 21 toward the second position. As the second die unit 22 moves toward the second position, the weakened portion 12 is torn off. FIG. 16 shows a part of the sheet material 10 in which the weakened portion 12 is torn off.

As shown in FIG. 9, the fulcrum portion 50 is inclined in an up-and-down direction at an angle θ1 from the one end 32d to the other end 32e relative to the lower surface 32b of the second die 32. With this configuration, while the relative movement of the second die unit 22 is small, the first support surface 51 strongly abuts against the sheet material 10. Consequently, high tensile stress develops near the one end 12a of the weakened portion 12, and the part closer to the end 12a fractures first.

As the second die unit 22 moves further relative to the first die unit 21, the second support surface 52 strongly abuts against the sheet material 10. Consequently, a large tensile force is generated near the other end 12b of the weakened portion 12, and thus the part near the other end 12b fractures later. In this manner, the weakened portion 12 is torn from the part near the one end 12a toward the part near the other end 12b. In this manner, it is possible to suppress vibrations and noise generated when the weakened portion 12 is torn.

Note here that the first support surface 51 and the second support surface 52 need not necessarily be connected continuously obliquely at an angle. For example, the first support surface 51 and the second support surface 52 may have such a shape where the height changes stepwise. The number of holes 13 in the weakened portion 12 may be any number, and the shapes of these holes 13 may be identical to each other.

As described above, the tearing method for the sheet material in this embodiment includes the following steps.
(1) Overlay the base component 2 and the sheet component 4 of the sheet material 10 one on another, and fix theses using the first die unit 21. The first die unit 21 has a fulcrum portion 50 that supports the sheet material 10 in the thickness direction when tearing the weakened portion 12. The fulcrum portion 50 has a first support surface 51 and a second support surface 52, and is inclined at an angle θ1.
(2) Fix the frame portion 11 of the sheet material 10 by the second die unit 22.
(3) Move the second die unit 22 relative to the first die unit 21 in the thickness direction of the sheet material 10, to make the sheet material 10 to abut against the fulcrum portion 50, thereby generating tension in the sheet material 10.
(4) When the second die unit 22 moves relatively, while the amount of movement is small, a tensile force that tears off the portion near the one end 12a of the weakened portion 12 is generated by the first support surface 51. Thus, the portion near the one end 12a of the weakened portion 12 is torn off.
(5) As the amount of movement of the second die unit 22 relative to the first die unit 21 increases, a tensile force that tears off the portion near the other end 12b of the weakened portion 12 is generated by the second support surface 52. Thus, the portion near the other end 12b of the weakened portion 12 is torn off.

### Second Embodiment

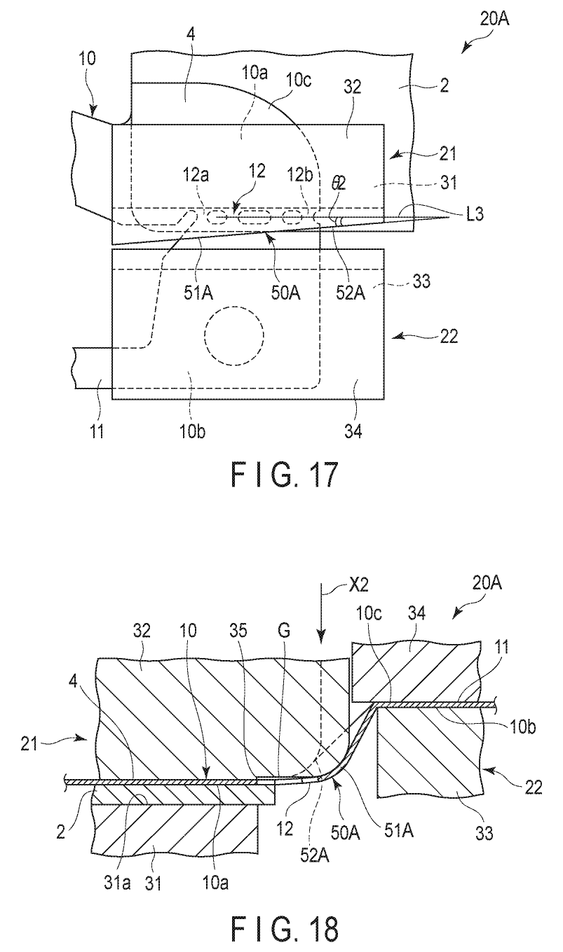

FIG. 17 is a plan view showing a die set 20A according to the second embodiment. FIG. 18 is a cross-sectional view showing a part of the die set 20A and the sheet material 10 in the process of being torn off. The die set 20A shown in FIG. 17, as in the case of the die set 20 of the first embodiment, has a first die unit 21 and a second die unit 22. A fulcrum portion 50A is formed on the first die unit 21.

FIGS. 17 and 18 show the fulcrum portion 50A of the die set 20A. The line segment L3 shown in FIG. 17 extends in the lengthwise direction of the weakened portion 12 when viewed from the direction facing the plane 10c of the sheet material 10 (indicated by arrow X2 in FIG. 18). The fulcrum portion 50A extends in an oblique direction at an angle θ2 relative to the line segment L3. That is, when viewed from the direction facing the plane 10c of the sheet material 10, the fulcrum portion 50A has a shape where the distance from the weakened portion 12 decreases from the side closer to one end 12a of the weakened portion 12 toward the side closer to the other end 12b.

The angle θ2 of the fulcrum portion 50A is 1° or more and 5° or less, a reason similar to that of the angle θ1 of the fulcrum portion 50 described in the first embodiment. More preferably, θ2 is 1° or more and 3° or less. Regarding other configurations, the die set 20A of the second embodiment is similar to the die set 20 of the first embodiment, and therefore common parts are denoted by common reference numerals, and descriptions thereof are omitted.

FIG. 18 shows the state where the second die unit 22 has moved relative to the first die unit 21 in the thickness direction of the sheet material 10. While the movement amount of the second die unit 22 is small, tensile force tearing the part near the one end 12a of the weakened portion 12 is generated by the first support surface 51A. As the amount of movement of the second die unit 22 increases, tensile force tearing the part near the other end 12b of the weakened portion 12 is generated by the second support surface 52A. Consequently, the weakened portion 12 is torn off from the part near the one end 12a toward the part near the other end 12b.

It goes without saying that when implementing the present invention, the specific shapes and arrangements of each part constituting the die set can be varied in various ways. A fulcrum portion having such a shape that the fulcrum portion 50 of the first embodiment and the fulcrum portion 50A of the second embodiment are combined may as well do. Various forms of sheet material and weakened portion can be applied as well.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A die set comprising:
a first die unit which fixes a first portion of a sheet material;
a second die unit which fixes a second portion of the sheet material and moves relative to the first die unit in a thickness direction of the sheet material; and
a fulcrum portion located to face the sheet material, which is brought into contact with the sheet material when the first die unit and the second die unit move relative to each other in the thickness direction of the sheet material, and generates a tensile force to tear the sheet material, wherein
the fulcrum portion includes:
a first support surface which is located at a position to generate a tensile force to tear a part near one end of the weakened portion when an amount of movement of the second die unit with respect to the first die unit is small, and
a second support surface which is located at a position to generate a tensile force to tear a part near the other end of the weakened portion when an amount of movement of the second die unit with respect to the first die unit increases.

2. The die set according to claim 1, wherein
the fulcrum portion has such an oblique shape that, as viewed from a direction facing the plane of the sheet material, a distance from the sheet material increases from a side closer to one end of the weakened portion toward a side closer to an other end.

3. The die set according to claim 1, wherein
the fulcrum portion has such an oblique shape that, as viewed from a direction facing the plane of the sheet material, a distance from the weakened portion decreases from a side closer to one end of the weakened portion toward a side closer to an other end.

4. A method for tearing a sheet material, comprising:
fixing a first portion of the sheet material by a first die unit;
fixing a second portion of the sheet material by a second die unit; and
moving the first die unit and the second die unit relative to each other in a thickness direction of the sheet material, thereby bringing the sheet material into contact a fulcrum portion and generating a tensile force to tear a weakened portion of the sheet material by the fulcrum portion,
the method further comprising:
generating, while an amount of movement of the second die unit relative to the first die unit is small, a tensile force on the weakened portion to tear a part near one end of the weakened portion by the first support surface of the fulcrum portion; and
generating, as the amount of movement of the second die unit relative to the first die unit increases, a tensile force on the weakened portion to tear a part near an other end of the weakened portion by the second support surface of the fulcrum portion.
